(19) United States
(12) Patent Application Publication
(10) Pub. No.: US 2026/0050384 A1
(43) Pub. Date: Feb. 19, 2026

(54) STORAGE DEVICE AND METHOD OF OPERATING THE SAME

(71) Applicant: SK hynix Inc., Gyeonggi-do (KR)

(72) Inventor: Eun Jae OCK, Gyeonggi-do (KR)

(21) Appl. No.: 19/180,144

(22) Filed: Apr. 16, 2025

(30) Foreign Application Priority Data
Aug. 16, 2024 (KR) 10-2024-0109978

(51) Int. Cl. G06F 3/06

(52) U.S. Cl. CPC G06F 3/0619; G06F 3/0659; G06F 3/0673

(57) ABSTRACT

Provided herein are a storage device and a method of operating the same. A memory controller having improved erase performance may include a status information storage and an operation controller. The status information storage may be configured to store status information of a memory block or the memory controller. The operation controller may be configured to determine an operation mode for an erase operation on the memory block based on the status information, and control a memory device to sequentially perform a pre-program operation and the erase operation, or perform the erase operation, depending on the operation mode.

### CROSS-REFERENCE TO RELATED APPLICATION

The present application claims priority under 35 U.S.C. § 119 (a) to Korean patent application number 10-2024-0109978 filed on Aug. 16, 2024, the entire disclosure of which is incorporated herein by reference.

### BACKGROUND

### 1. Field of Invention

Various embodiments of the present disclosure generally relate to an electronic device, and more particularly to a storage device and a method of operating the storage device.

### 2. Description of Related Art

A storage device stores data under the control of a host device, such as a computer or a smartphone. The storage device may include a memory device in which data is stored and a controller which controls the memory device. Memory devices are classified as either a volatile memory device or a nonvolatile memory device.

The volatile memory device may be a memory device in which data is stored only when power is supplied and in which stored data is lost when the supply of power is interrupted. Examples of the volatile memory device may include a static random access memory (SRAM) and a dynamic random access memory (DRAM).

The nonvolatile memory device is a memory device in which stored data is retained even when the supply of power is interrupted. Examples of the nonvolatile memory device include a read only memory (ROM), a programmable ROM (PROM), an electrically programmable ROM (EPROM), an electrically erasable and programmable ROM (EEPROM), and a flash memory.

### SUMMARY

Various embodiments of the present disclosure are directed to a storage device having improved erase performance, and a method of operating the storage device.

An embodiment of the present disclosure may provide for a memory controller. The memory controller may include a status information storage and an operation controller. The status information storage may be configured to store status information of a memory block or the memory controller. The operation controller may be configured to determine an operation mode for an erase operation on the memory block based on the status information, and control a memory device to sequentially perform a pre-program operation and the erase operation, or perform the erase operation, depending on the operation mode.

An embodiment of the present disclosure may provide for a storage device. The storage device may include a memory device and a memory controller. The memory device may include a memory block. The memory controller may be configured to store status information of the memory block or the memory controller, determine an operation mode indicating whether a pre-program operation is to be performed before an erase operation on the memory block based on the status information, and control the memory device to sequentially perform the pre-program operation and the erase operation, or perform the erase operation, depending on the operation mode.

An embodiment of the present disclosure may provide for a method of operating a storage device including a memory device and a memory controller. The method may include determining an operation mode for an erase operation on a memory block included in the memory device based on status information of the memory block or the memory controller, and sequentially performing a pre-program operation and the erase operation or performing the erase operation, depending on the operation mode.

### BRIEF DESCRIPTION OF THE DRAWINGS

FIG. 1 is a diagram illustrating a storage device.

FIG. 2 is a diagram illustrating a memory device of FIG. 1.

FIG. 3 is a diagram illustrating the structure of a memory block of FIG. 2.

FIG. 4 is a diagram illustrating the structure and operation of a memory controller of FIG. 1.

FIG. 5 is a diagram illustrating status information and the operation mode of an erase operation set based on the status information according to an embodiment of the present disclosure.

FIG. 6 is a diagram illustrating block information included in the status information of FIG. 5.

FIG. 7 is a diagram illustrating temperature information included in the status information of FIG. 5.

FIG. 8 is a diagram illustrating power information included in the status information of FIG. 5.

FIG. 9 is a diagram illustrating a pre-program operation and an erase operation.

FIG. 10 is a flowchart illustrating the operation of a storage device according to an embodiment of the preset disclosure.

FIG. 11 is a flowchart illustrating the operation of a storage device according to an embodiment of the present disclosure.

### DETAILED DESCRIPTION

Specific structural or functional descriptions in the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in the specification.

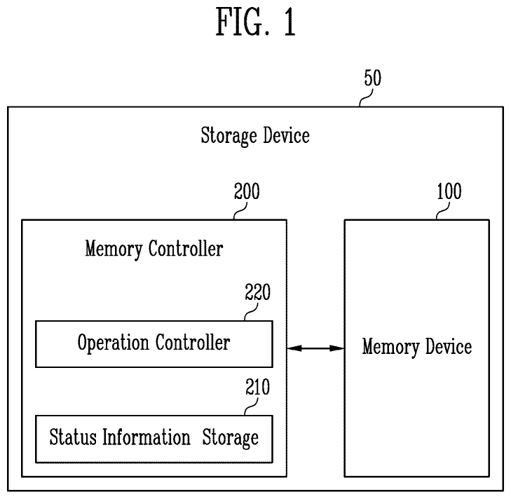

FIG. 1 is a diagram illustrating a storage device 50.

Referring to FIG. 1, the storage device 50 may include a memory device 100 and a memory controller 200. The storage device 50 may store data under the control of a host, such as a mobile phone, a smartphone, a laptop computer, a desktop computer, a game console, a smart television (TV), a tablet PC, or an in-vehicle infotainment system. In an embodiment, the storage device 50 may be a device such as a server or a data center, controlled by the host, through wired/wireless communication for storing data at a remote place.

The storage device 50 may interface with the host in various communication schemes, and may be implemented using various devices depending on the interfacing scheme. For example, the storage device 50 may be implemented as any of various types of storage devices, such as a solid state drive (SSD), an embedded multimedia card (eMMC), a SD, mini-SD, or micro-SD-type secure digital card, a universal serial bus (USB) storage device, a universal flash storage (UFS) device, a personal computer memory card international association (PCMCIA) card-type storage device, a peripheral component interconnection (PCI) card-type storage device, a PCI express (PCI-e or PCIe) card-type storage device, a compact flash (CF) card, and a smart media card.

In an embodiment, the storage device 50 may be manufactured in any of various types of package forms. For example, the storage device 50 may be manufactured in any of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may be operated in response to the control of the memory controller 200. The memory device 100 may include a plurality of memory cells which store data. Each of the memory cells may store one data bit or a plurality of data bits.

The memory cells may be accessed in units of a preset size depending on the type of memory device. The unit in which the memory cells are accessed may vary depending on each operation. For example, the memory cells may be accessed in units of different sizes for a write operation (program operation) of storing data in each memory cell, a read operation of measuring data stored in each memory cell, and an erase operation of erasing data stored in each memory cell.

In an embodiment, the memory device 100 may be a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM), a NAND flash memory, a vertical NAND flash memory, a NOR flash memory, a resistive RAM (RRAM), a phase-change memory (PCM), a magnetoresistive RAM (MRAM), a ferroelectric RAM (FRAM), or a spin transfer torque RAM (STT-RAM).

The memory device 100 may receive a command and an address from the memory controller 200, and may access the area of the memory cell array, selected by the address. The memory device 100 may perform an operation indicated by the command on the area selected by the address. For example, the memory device 100 may perform a write operation (program operation), a read operation, and an erase operation. During a program operation, the memory device 100 may write data to the area selected by the address. During a read operation, the memory device 100 may read data from the area selected by the address. During an erase operation, the memory device 100 may erase data stored in the area selected by the address.

The memory controller 200 may control the overall operation of the storage device 50.

When power is applied to the storage device 50, the memory controller 200 may run firmware (FW). The storage device 50 may translate a logical block address (LBA), provided by the host, into a physical address (i.e., a physical block address: PBA) used by the memory device 100. The logical block address (LBA) may be an address for identifying data provided by the host. The physical address (PBA) may be an address indicating a position at which data is stored in the memory device 100. In the present specification, the logical block address (LBA) may have the same meaning as a logical address, and the physical block address (PBA) may have the same meaning as the physical address.

The memory controller 200 may control the memory device 100 to perform a write operation, a read operation or an erase operation in response to a request received from the host. During the write operation, the memory controller 200 may provide a write command (program command), an address, and data to the memory device 100. During the read operation, the memory controller 200 may provide a read command and an address to the memory device 100. During the erase operation, the memory controller 200 may provide an erase command and an address to the memory device 100.

In an embodiment, the memory controller 200 may include a status information storage 210 and an operation controller 220.

The status information storage 210 may store status information of the memory device 100 and the memory controller 200. For example, the status information storage 210 may store information about memory blocks included in the memory device 100. The status information storage 210 may store information about the temperature and power supply of the memory controller 200.

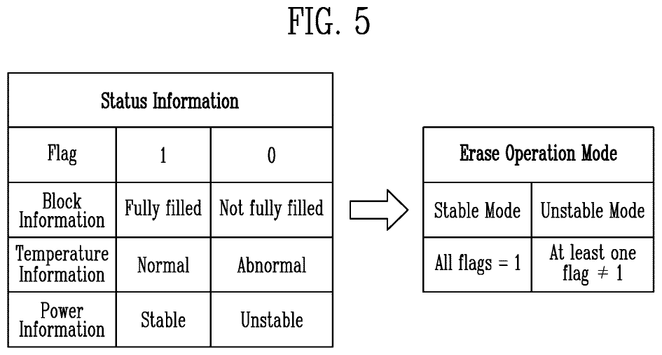

The operation controller 220 may set the operation mode of an erase operation on each memory block to a stable mode or an unstable mode based on the status information. Setting the operation mode of the erase operation will be described later with reference to FIG. 5. The operation controller 220 may control the memory device 100 to selectively perform a pre-program operation before the erase operation, and then perform the erase operation, depending on the operation mode.

For example, when the operation mode is the unstable mode, the operation controller 220 may control the memory device 100 to perform the erase operation after performing the pre-program operation on the memory block. When the operation mode is the stable mode, the operation controller 220 may control the memory device 100 to skip the pre-program operation on the memory block and perform the erase operation.

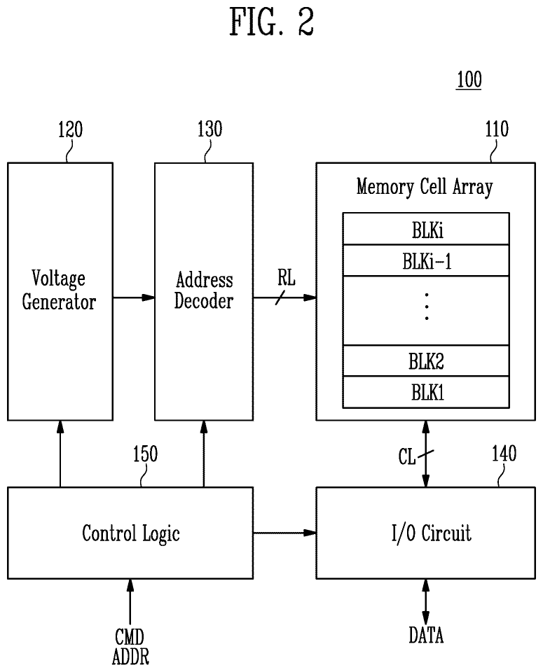

FIG. 2 is a diagram illustrating the memory device 100 of FIG. 1.

Referring to FIG. 2, the memory device 100 may include a memory cell array 110, a voltage generator 120, an address decoder 130, an input and output (input/output) (I/O) circuit 140, and a control logic 150.

The memory cell array 110 may include a plurality of memory blocks BLK1 to BLKi. The plurality of memory blocks BLK1 to BLKi are connected to the address decoder 130 through row lines RL. The plurality of memory blocks BLK1 to BLKi may be connected to the input/output circuit 140 through column lines CL. In an embodiment, the row lines RL may include word lines, source select lines, and drain select lines. In an embodiment, the column lines CL may include bit lines.

Each of the memory blocks BLK1 to BLKi may include a plurality of memory cells. In an embodiment, the plurality of memory cells may be nonvolatile memory cells. Memory cells connected to the same word line, among the plurality of memory cells, may be defined as one page. That is, each of the memory blocks BLK1 to BLKi may include a plurality of pages.

Each of the memory cells included in the memory cell array 110 may be implemented as a single-level cell (SLC) capable of storing one data bit, a multi-level cell (MLC) capable of storing two data bits, a triple-level cell (TLC) capable of storing three data bits, or a quad-level cell (QLC) capable of storing four data bits.

In an embodiment, the voltage generator 120, the address decoder 130, and the input/output circuit 140 may be collectively referred to as a peripheral circuit. The peripheral circuit may drive the memory cell array 110 under the control of the control logic 150. The peripheral circuit may drive the memory cell array 110 to perform a write operation (program operation), a read operation, and an erase operation.

The voltage generator 120 may generate a plurality of operating voltages using an external supply voltage provided to the memory device 100. The voltage generator 120 may be operated under the control of the control logic 150. In an embodiment, the voltage generator 120 may generate an internal supply voltage by regulating the external supply voltage. The internal supply voltage generated by the voltage generator 120 may be used as an operating voltage for the memory device 100.

In an embodiment, the voltage generator 120 may generate a plurality of operating voltages using the external supply voltage or the internal supply voltage. The voltage generator 120 may generate various voltages required by the memory device 100. For example, the voltage generator 120 may generate a plurality of erase voltages, a plurality of program voltages, a plurality of pass voltages, a plurality of select read voltages, and a plurality of unselect read voltages.

The voltage generator 120 may include a plurality of pumping capacitors for receiving the internal supply voltage to generate a plurality of operating voltages having various voltage levels. The voltage generator 120 may generate a plurality of operating voltages by selectively enabling the plurality of pumping capacitors under the control of the control logic 150.

The plurality of generated operating voltages may be supplied to the memory cell array 110 by the address decoder 130.

The address decoder 130 is connected to the memory cell array 110 through the row lines RL. The address decoder 130 may be operated in response to control of the control logic 150. The address decoder 130 may receive addresses ADDR from the control logic 150. The address decoder 130 may decode a block address among the received addresses ADDR. The address decoder 130 may select at least one of the memory blocks BLK1 to BLKi according to the decoded block address. The address decoder 130 may decode a row address among the received addresses ADDR. The address decoder 130 may select at least one of word lines of the selected memory block according to the decoded row address. In an embodiment, the address decoder 130 may decode a column address among the received addresses ADDR. The address decoder 130 may connect the input/output circuit 140 to the memory cell array 110 according to the decoded column address.

In an embodiment, the address decoder 130 may include components, such as a row decoder, a column decoder, and an address buffer.

The input/output circuit 140 may include a plurality of page buffers. The plurality of page buffers may be connected to the memory cell array 110 through the bit lines. During a write operation (program operation), data may be stored in the selected memory cells depending on the data stored in the plurality of page buffers. During a read operation, data stored in the selected memory cells may be measured through the bit lines, and the measured data may be stored in the page buffers.

The control logic 150 may control the address decoder 130, the voltage generator 120, and the input/output circuit 140. The control logic 150 may be operated in response to a command CMD transmitted from an external device. The control logic 150 may control the peripheral circuit by generating control signals in response to the command CMD and the addresses ADDR.

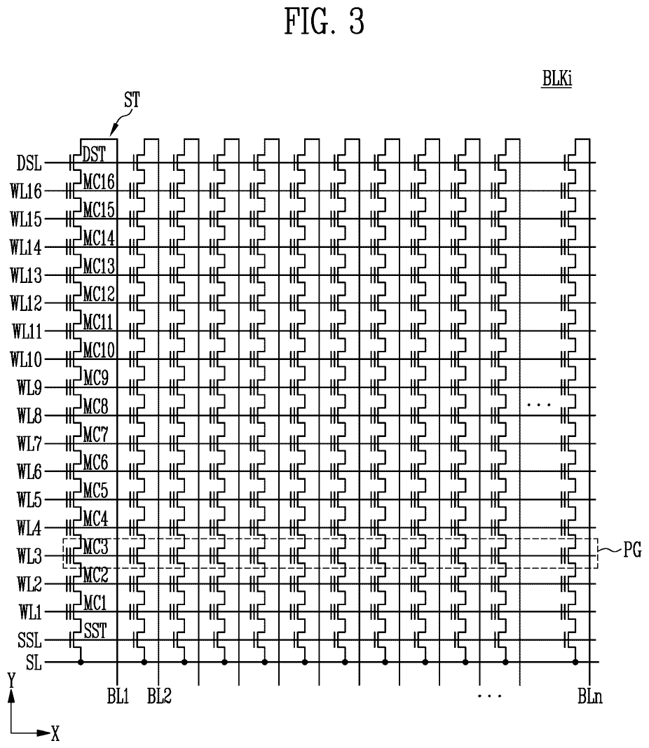

FIG. 3 is a diagram illustrating the structure of one of the memory blocks of FIG. 2.

The memory block BLKi may indicate one memory block BLKi among the memory blocks BLK1 to BLKi of FIG. 2.

Referring to FIG. 3, memory cells may be connected to a plurality of word lines arranged between a first select line and a second select line. Here, the first select line may be a source select line SSL, and the second select line may be a drain select line DSL. In detail, the memory block BLKi may include a plurality of strings ST connected between bit lines BL1 to BLn and a source line SL. The bit lines BL1 to BLn may be connected to the strings ST, respectively. The source line SL may be connected in common to the strings ST. Since the strings ST may be equally configured, a string ST connected to the first bit line BL1 will be described in detail by way of example.

The string ST may include a source select transistor SST, a plurality of memory cells MC1 to MC16, and a drain select transistor DST which are connected in series to each other between the source line SL and the first bit line BL1. A single string ST may include at least one source select transistor SST and at least one drain select transistor DST, and more memory cells than the memory cells MC1 to MC16 illustrated in the drawing may be included in the string ST.

A source of the source select transistor SST may be connected to the source line SL. A drain of the drain select transistor DST may be connected to the first bit line BL1. The memory cells MC1 to MC16 may be connected in series between the source select transistor SST and the drain select transistor DST. Gates of the source select transistors SST included in different strings ST may be connected to the source select line SSL. Gates of the drain select transistors DST included in different strings ST may be connected to the drain select line DSL. Gates of the memory cells MC1 to MC16 may be connected to a plurality of word lines WL1 to WL16, respectively. A group of memory cells connected to the same word line, among the memory cells included in different strings ST, may be a page (PG). Therefore, the memory block BLKi may include a number of pages (PG) identical to the number of word lines WL1 to WL16.

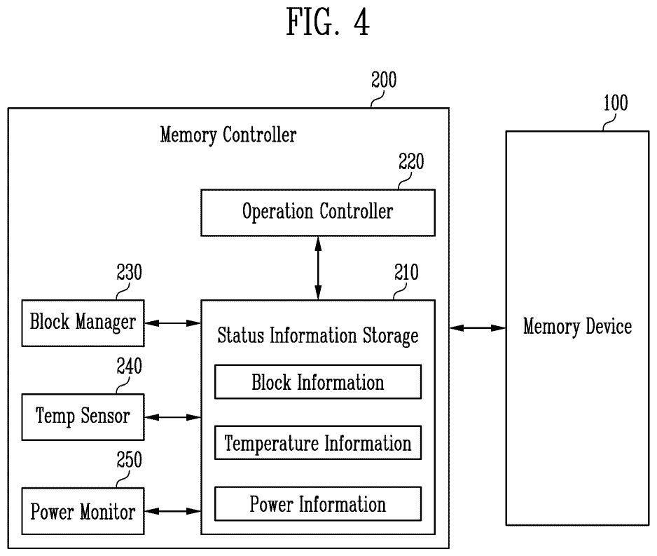

FIG. 4 is a diagram illustrating the structure and operation of the memory controller 200 of FIG. 1.

Referring to FIG. 4, the memory device 100 may include a plurality of memory blocks which store data. The memory device 100 may perform a pre-program operation or an erase operation on each memory block, under the control of the memory controller 200.

The memory controller 200 may include a status information storage 210, an operation controller 220, a block manager 230, a temperature (Temp) sensor 240, and a power monitor 250.

The status information storage 210 may store status information of the memory blocks included in the memory device 100 and the memory controller 200.

The status information may include block information, temperature information, and power information. The block information may indicate whether the last word line of the corresponding memory block has been programmed. The temperature information may indicate whether the temperature of the memory controller 200 is normal. In an embodiment, the temperature information may be information about the temperature of the memory device 100, the storage device 50 described with reference to FIG. 1, or a system on chip (SOC) package including the storage device 50, as well as the memory controller 200. The power information may indicate whether the supply of power to the memory controller 200 is stable. In an embodiment, the power information may be information about the supply of power to the memory device 100, the storage device 50, or the SoC package, as well as the memory controller 200.

The operation controller 220 may set the operation mode of the erase operation on the memory block based on the status information. The operation controller 220 may set the operation mode to the stable mode when respective flag values of the block information, the temperature information, and the power information are identical to preset values. The operation controller 220 may set the operation mode to the unstable mode when at least one of the flag values of the block information, the temperature information, and the power information is different from a preset value. This will be described in detail later with reference to FIG. 5.

The operation controller 220 may selectively perform a pre-program operation before the erase operation, based on the checking result of the operation mode. The operation controller 220 may control the memory device 100 to perform the erase operation. The pre-program operation may be an operation of increasing the threshold voltages of all memory cells included in the memory block to a preset level to prevent over-erasure or shallow erasure.

When the operation mode is the unstable mode, the operation controller 220 may control the memory device 100 to perform the erase operation after performing the pre-program operation. When the operation mode is the stable mode, the operation controller 220 may control the memory device 100 to skip the pre-program operation and perform the erase operation.

The block manager 230 may generate the block information based on meta-information stored in the memory block. The meta-information may be information related to the data stored in the memory block, and may include journal data, parity data, mapping data, etc. The block manager 230 may determine, based on the meta-information, whether the last word line in the memory block has been programmed, and may set the flag value of the block information. For example, the block manager 230 may set the flag value of the block information to a first logic value when the last word line of the memory block has been programmed. The block manager 230 may set the flag value of the block information to a second logic value when the last word line of the memory block has not been programmed.

The block manager 230 may store the generated block information in the status information storage 210 or may update the block information stored in the status information storage 210.

The temperature sensor 240 may measure the temperature of the memory controller 200 and generate temperature information either at preset periods or in response to a preset event. In an embodiment, the temperature sensor 240 may measure the temperature of the memory device 100, the storage device 50 or the SoC package, as well as the memory controller 200. When the measured temperature falls within a reference range, the temperature sensor 240 may set the flag value of the temperature information to a first logic value. When the measured temperature falls out of the reference range, the temperature sensor 240 may set the flag value of the temperature information to a second logic value.

The power monitor 250 may monitor whether the supply of power to the memory controller 200 is stable. In an embodiment, the power monitor 250 may monitor whether the supply of power to the memory device 100, the storage device 50 or the SoC package, as well as the memory controller 200, is stable. The power monitor 250 may monitor a low-voltage drop count and an abnormal shutdown count of the memory controller 200, and may generate the power information. When the low-voltage drop count is less than or equal to a first reference value and the abnormal shutdown count is less than or equal to a second reference value, the power monitor 250 may set the flag value of the power information to a first logic value. When the low-voltage drop count is greater than the first reference value or the abnormal shutdown count is greater than the second reference value, the power monitor 250 may set the flag value of the power information to a second logic value.

According to the embodiment described with reference to FIG. 4, when the operation mode is the stable mode, there is no concern regarding over-erasure or shallow erasure, and thus the pre-program operation on the memory block is skipped, and the erase operation is immediately performed, with the result that total time required for the erase operation may be shortened.

FIG. 5 is a diagram illustrating status information and the operation mode of an erase operation set based on the status information according to an embodiment of the present disclosure.

Referring to FIG. 5, status information may include respective flag values of block information, temperature information, and power information.

The block information may indicate, as a flag value, whether the last word line of the corresponding memory block has been programmed. For example, a flag value of 1 may indicate that the last word line has been programmed, and may represent the state in which the memory block is fully filled with program data. A flag value of 0 may indicate that the last word line has not been programmed, and may represent the state in which the memory block is not fully filled with program data.

The temperature information may indicate, as a flag value, whether the temperature of the memory controller 200 is normal. For example, a flag value of 1 may indicate a normal state in which the temperature falls within a reference range. A flag value of 0 may indicate an abnormal state in which the temperature falls out of the reference range.

The power information may indicate, as a flag value, whether the supply of power to the memory controller is stable. For example, a flag value of 1 may indicate that the supply of power is stable. A flag value of 0 may indicate that the supply of power is unstable.

The operation mode of the erase operation may be set to a stable mode or an unstable mode.

For example, when the flag values of all of the block information, the temperature information, and the power information are 1, the operation mode may be set to the stable mode. When at least one of the respective flag values of the block information, the temperature information, and the power information is not 1, the operation mode may be set to the unstable mode.

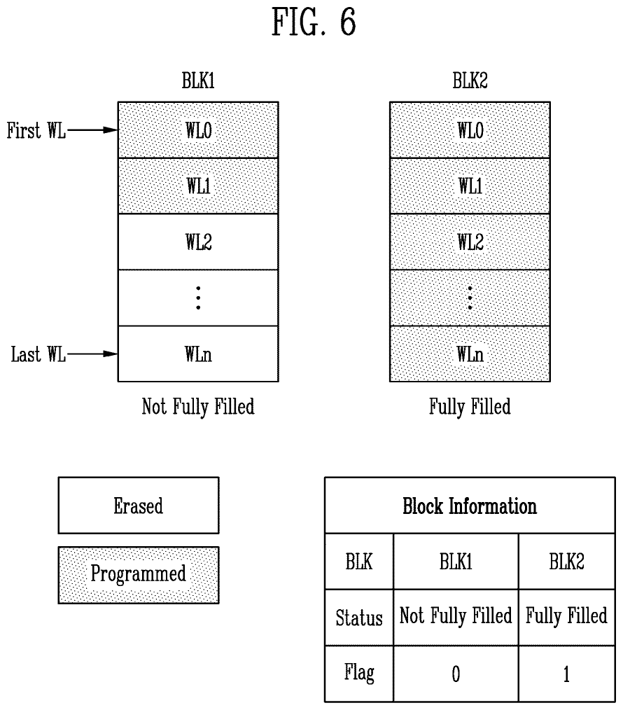

FIG. 6 is a diagram illustrating block information included in the status information of FIG. 5.

Referring to FIG. 6, the block information may indicate, as a flag value, whether the last word line (WL) of the corresponding memory block has been programmed. For example, when the last word line has been programmed, the flag value may be 1, whereas when the last word line has not been programmed, the flag value may be 0.

In FIG. 6, a memory block BLK1 is in the state in which only some word lines WL0 and WL1 have been programmed (i.e., not fully filled), and thus the flag value of the memory block BLK1 may be 0. A memory block BLK2 is in the state in which all word lines WL0 to WLn ranging from the first word line WL0 to the last word line WLn have been programmed (i.e., fully filled), and thus the flag value of the memory block BLK2 may be 1.

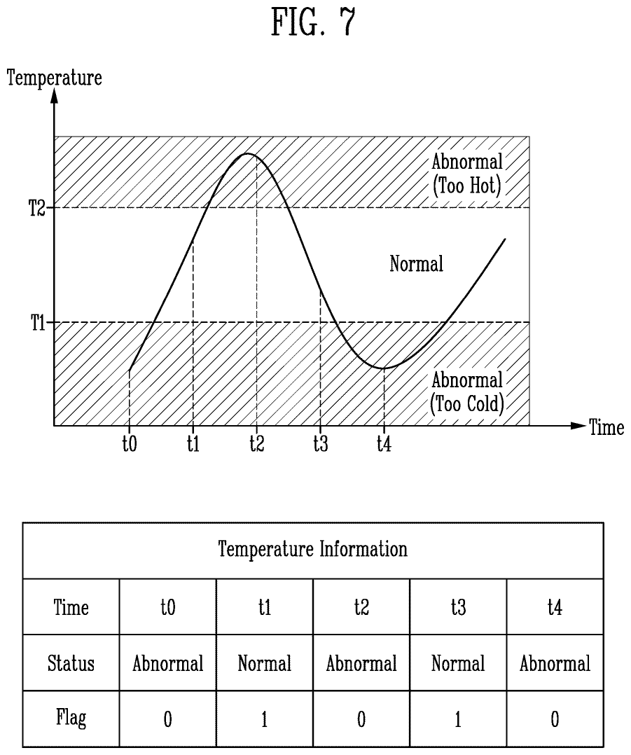

FIG. 7 is a diagram illustrating temperature information included in the status information of FIG. 5.

Referring to FIG. 7, the temperature information may indicate, as a flag value, whether the temperature of a memory controller is normal. For example, when the temperature falls within a reference range, the flag value may be 1, whereas when the temperature falls out of the reference range, the flag value may be 0.

In FIG. 7, the reference range may be a range between T1 and T2. The temperature at time points t0, t2, and t4 falls out of the reference range, and thus the flag value may be 0 (i.e., abnormal). The temperature at time points t1 and t3 falls within the reference range, and thus the flag value may be 1 (i.e., normal).

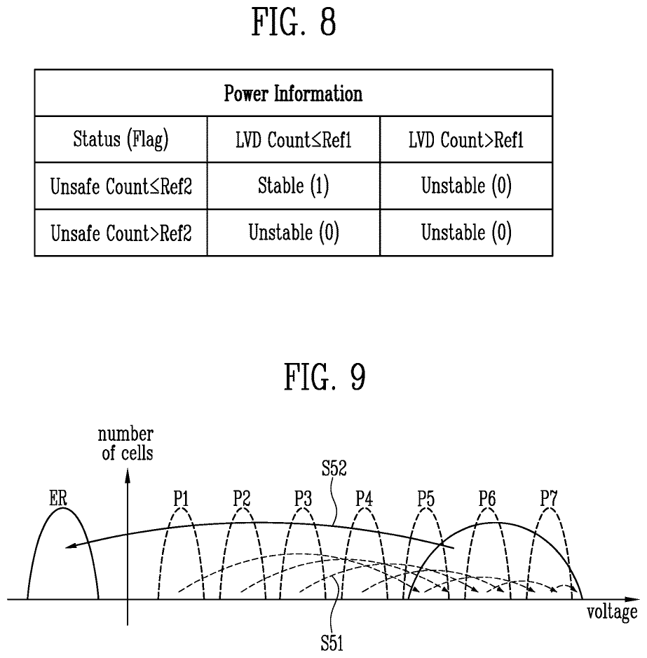

FIG. 8 is a diagram illustrating power information included in the status information of FIG. 5.

Referring to FIG. 8, the power information may indicate, as a flag value, whether the supply of power to a memory controller is stable. For example, when the supply of power is stable, the flag value may be 1, whereas when the supply of power is unstable, the flag value may be 0.

In FIG. 8, when a low-voltage drop count (LVD Count) is less than or equal to a first reference value (Ref1) and an abnormal shutdown count (Unsafe Count) is less than or equal to a second reference value (Ref2), the memory controller may set the flag value of the power information to a first logic value (1) (i.e., stable). When the low-voltage drop count is greater than the first reference value (Ref1) or the abnormal shutdown count is greater than the second reference value (Ref2), the memory controller may set the flag value of the power information to a second logic value (0) (i.e., unstable).

FIG. 9 is a diagram illustrating a pre-program operation and an erase operation.

Referring to FIG. 9, a pre-program operation S51 may be performed before an erase operation S52 is performed. For example, a memory device may sequentially perform the pre-program operation S51 and the erase operation S52 on a selected memory block. Before an erase command is input, memory cells may be in the state in which they are programmed to various states. Therefore, the pre-program operation S51 may be an operation of increasing the threshold voltages of memory cells to a preset level before the erase operation S52 is performed to prevent the erase operation S52 from being excessively performed or being insufficiently performed on the memory cells.

For example, in the case of memory cells programmed according to a triple-level cell (TLC) scheme in which 3 bits of data are stored in one memory cell, the memory cells may be in an erase state ER or any of first to seventh program states P1 to P7 depending on the threshold voltages thereof. When the pre-program operation S51 is performed before the erase operation S52 is performed, threshold voltages corresponding to the erase state ER and the first to seventh program states P1 to P7 may be increased. During the pre-program operation S51, a program voltage may be applied once to all word lines connected to the selected memory block. After the program voltage is applied, a verify operation may be skipped. The number of times the program voltage is applied may be changed. The program voltage used in the pre-program operation S51 may be set to the highest voltage among program voltages, but it may be set to various levels according to the setting of the pre-program operation S51. During the pre-program operation S51, as the threshold voltages of memory cells are lower, the variation level of the threshold voltages may be increased.

When the pre-program operation S51 is terminated, the erase operation S52 may be performed on the selected memory block. The erase operation S52 may be an operation of changing all memory cells included in the selected memory block to the erase state ER, wherein an erase voltage may be applied to a source line or bit lines of the selected memory block and a ground voltage may be applied to all word lines thereof. Because the memory cells are erased in the state in which the threshold voltages of the memory cells become greater than those in a previous state due to the pre-program operation S51, a phenomenon in which the threshold voltages in the erase state ER are excessively decreased or insufficiently decreased may be prevented.

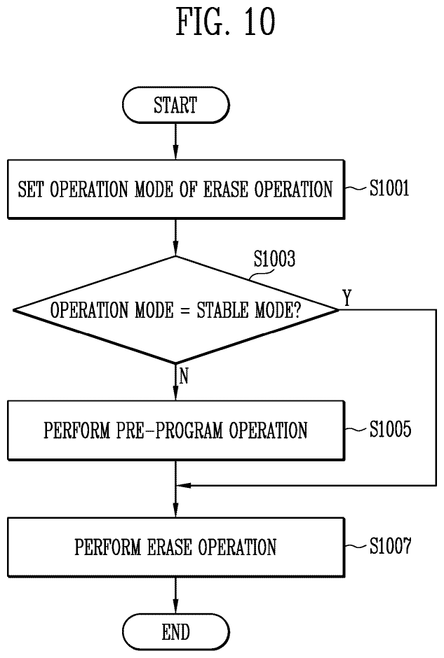

FIG. 10 is a flowchart illustrating the operation of a storage device according to an embodiment of the present disclosure.

Referring to FIG. 10, at S1001, the storage device may set the operation mode of an erase operation on a memory block to a stable mode or an unstable mode.

At S1003, the storage device may determine whether the operation mode is a stable mode. When it is determined that the operation mode is the stable mode (S1003, Y), the storage device may proceed to S1007. When it is determined that the operation mode is the unstable mode (S1003, N), the storage device may proceed to S1005.

At S1005, the storage device may perform a pre-program operation on the memory block.

At S1007, the storage device may perform an erase operation on the memory block.

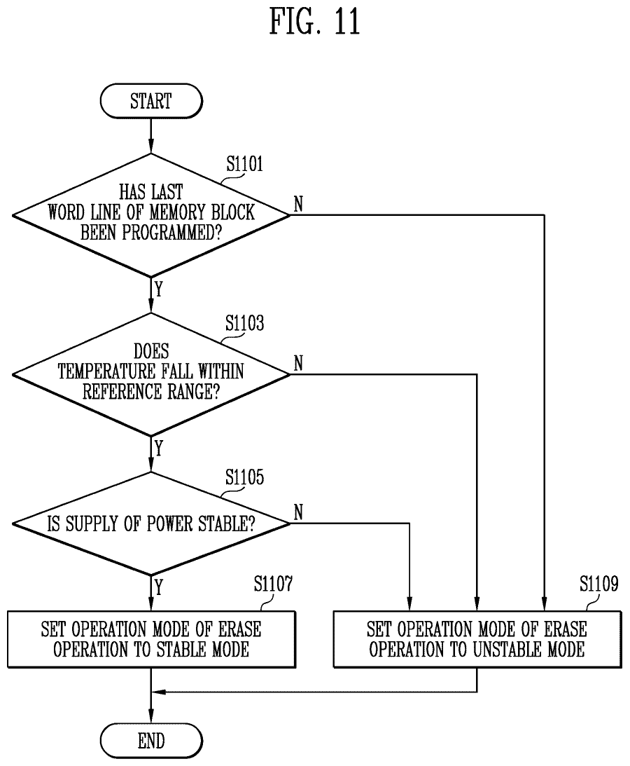

FIG. 11 is a flowchart illustrating the operation of a storage device according to an embodiment of the present disclosure.

Referring to FIG. 11, a detailed process of S1001 of FIG. 10 is illustrated.

At S1101, the storage device may determine whether the last word line of the memory block has been programmed. When it is determined that the last word line has been programmed (S1101, Y), the storage device may proceed to S1103. When it is determined that the last word line has not been programmed (S1101, N), the storage device may proceed to S1109.

At S1103, the storage device may determine whether temperature falls within a reference range. When it is determined that the temperature falls within the reference range (S1103, Y), the storage device may proceed to S1105. When it is determined that the temperature falls out of the reference range (S1103, N), the storage device may proceed to S1109.

At S1105, the storage device may determine whether the supply of power is stable. When it is determined that the supply of power is stable (S1105, Y), the storage device may proceed to S1107. When it is determined that the supply of power is unstable (S1105, N), the process may proceed to S1109.

At S1107, the storage device may set the operation mode of the erase operation to the stable mode.

At S1109, the storage device may set the operation mode of the erase operation to the unstable mode.

According to the embodiments of the present disclosure, there are provided a storage device having improved erase performance, and a method of operating the storage device. Furthermore, the embodiments may be combined to form additional embodiments.

What is claimed is:

1. A memory controller comprising:
a status information storage configured to store status information of a memory block or the memory controller; and
an operation controller configured to determine an operation mode for an erase operation on the memory block based on the status information, and control a memory device to sequentially perform a pre-program operation and the erase operation, or perform the erase operation, depending on the operation mode.

2. The memory controller according to claim 1, wherein the operation controller is configured to control the memory device to perform the erase operation after performing the pre-program operation when it is determined that the operation mode is an unstable mode.

3. The memory controller according to claim 1, wherein the operation controller is configured to control the memory device to skip the pre-program operation and perform the erase operation when it is determined that the operation mode is a stable mode.

4. The memory controller according to claim 1, wherein the status information includes at least one of block information indicating whether a last word line of the memory block has been programmed, temperature information indicating whether a temperature of the memory controller is normal, and power information indicating whether supply of power to the memory controller is stable.

5. The memory controller according to claim 4, wherein the operation controller is configured to determine the operation mode as a stable mode when respective flag values of the block information, the temperature information, and the power information are identical to preset values, and to determine the operation mode as an unstable mode when at least one of the flag values of the block information, the temperature information, and the power information is different from the corresponding preset value.

6. The memory controller according to claim 4, further comprising:
a block manager configured to generate the block information based on meta-information stored in the memory block.

7. The memory controller according to claim 6, wherein the block manager is configured to determine the flag value of the block information as a first logic value when it is determined that the last word line of the memory block has been programmed, and to determine the flag value of the block information as a second logic value when it is determined that the last word line of the memory block has not been programmed.

8. The memory controller according to claim 4, further comprising:
a temperature sensor configured to measure the temperature of the memory controller and generate the temperature information.

9. The memory controller according to claim 8, wherein the temperature sensor is configured to determine the flag value of the temperature information to a first logic value when it is determined that the temperature of the memory controller falls within a reference range, and to determine the flag value of the temperature information as a second logic value when it is determined that the temperature of the memory controller falls out of the reference range.

10. The memory controller according to claim 4, further comprising:
a power monitor configured to monitor a low-voltage drop count and an abnormal shutdown count of the memory controller and generate the power information.

11. The memory controller according to claim 10, wherein the power monitor is configured to determine the flag value of the power information as a first logic value when it is determined that the low-voltage drop count is less than or equal to a first reference value and the abnormal shutdown count is less than or equal to a second reference value, and to determine the flag value of the power information as a second logic value when it is determined that the low-voltage drop count is greater than the first reference value or the abnormal shutdown count is greater than the second reference value.

12. The memory controller according to claim 1, wherein the pre-program operation includes an operation of increasing threshold voltages of memory cells included in the memory block to a preset level.

13. A storage device comprising:
a memory device including a memory block; and
a memory controller configured to store status information of the memory block or the memory controller,
determine an operation mode indicating whether a pre-program operation is to be performed before an erase operation on the memory block based on the status information, and
control the memory device to sequentially perform the pre-program operation and the erase operation, or perform the erase operation, depending on the operation mode.

14. The storage device according to claim 13, wherein the status information includes at least one of block information indicating whether a last word line of the memory block has been programmed, temperature information indicating whether a temperature of the memory controller is normal, and power information indicating whether supply of power to the memory controller is stable.

15. The storage device according to claim 14, wherein the memory controller is configured to control the memory device to determine the operation mode as a stable mode, skip the pre-program operation, and perform the erase operation when respective flag values of the block information, the temperature information, and the power information are identical to preset values.

16. A method of operating a storage device including a memory device and a memory controller, the method comprising:
determining an operation mode for an erase operation on a memory block included in the memory device based on status information of the memory block or the memory controller; and
sequentially performing a pre-program operation and the erase operation or performing the erase operation, depending on the operation mode.

17. The method according to claim 16, wherein sequentially performing the pre-program operation and the erase operation or performing the erase operation comprises:
sequentially performing the pre-program operation and the erase operation when it is determined that the operation mode is determined as an unstable mode, and
skipping the pre-program operation and performing the erase operation when it is determined that the operation mode is determined as a stable mode.

18. The method according to claim 16, wherein determining the operation mode comprises:
checking whether a last word line of the memory block has been programmed;
checking whether a temperature of the memory controller is normal;
checking whether supply of power to the memory controller is stable; and
determining the operation mode as a stable mode or an unstable mode based on the checking results.

19. The method according to claim 18, wherein checking whether the temperature is normal comprises:
measuring the temperature of the memory controller at preset periods; and
checking whether the temperature falls within a reference range.

20. The method according to claim 18, wherein checking whether the supply of power is stable comprises:
monitoring a low-voltage drop count and an abnormal shutdown count of the memory controller; and
checking whether the low-voltage drop count is less than or equal to a first reference value and the abnormal shutdown count is less than or equal to a second reference value.
